(19) United States
(12) Patent Application Publication
(10) Pub. No.: US 2008/0036544 A1
(43) Pub. Date: Feb. 14, 2008

(54) METHOD FOR ADJUSTING OSCILLATOR IN PHASE-LOCKED LOOP AND RELATED FREQUENCY SYNTHESIZER

(76) Inventor: Fucheng Wang, San Jose, CA (US)

Correspondence Address: NORTH AMERICA INTELLECTUAL PROPERTY CORPORATION, P.O. BOX 506, MERRIFIELD, VA, 22116, US

(21) Appl. No.: 11/781,961

(22) Filed: Jul. 24, 2007

Related U.S. Application Data
(60) Provisional application No. 60/821,821, filed on Aug. 8, 2006.

(51) Int. Cl. H03L 7/00

(52) U.S. Cl. 331/16

(57) ABSTRACT

A frequency synthesizer is disclosed. The frequency synthesizer includes a phase-locked loop (PLL) provided with an oscillator, a switching unit for switching the PLL to either an open loop status or a closed loop status, and a setting device for adjusting an oscillator frequency of the oscillator according to a reference clock and an oscillator signal generated from the oscillator when the PLL is in the open loop status, wherein a control signal of the oscillator is substantially constant when the PLL is in the open loop status.

### CROSS REFERENCE TO RELATED APPLICATIONS

This application claims the benefit of U.S. Provisional Application No. 60/821,821, filed on Aug. 8, 2006 and included herein by reference.

### BACKGROUND OF THE INVENTION

1. Field of the Invention

The present invention relates to a phase-locked loop (PLL) technology, and more particularly, to a method for adjusting an oscillator in a PLL, and related frequency synthesizers.

2. Description of the Prior Art

For many kinds of communication devices (such as mobile phones), Multi-Mode/Multi-Band applications are increasingly utilized, and a mobile communication device often uses a frequency synthesizer with a wide frequency adjusting range for providing required clock signals in this type of application.

In general, the frequency synthesizer is realized by using a phase-locked loop (PLL) scheme. The gain value of an oscillator in the PLL of the frequency synthesizer should be maintained at a low level so as to meet a strict requirement for the phase noise in the mobile communication standard. In order to attain the above purpose, most oscillators of the frequency synthesizer are realized by using a switched capacitor voltage-controlled oscillator (switched capacitor VCO) so as to increase the frequency adjusting range of the frequency synthesizer.

It is known that the locking speed of the PLL has a large influence on the whole efficiency of the frequency synthesizer. Thus, how to improve the locking speed of the PLL that uses a switched capacitor oscillator scheme is a problem requiring a solution.

### SUMMARY OF THE INVENTION

It is therefore one of the objectives of the present invention to provide a method for adjusting an oscillator in a phase-locked loop (PLL) and related frequency synthesizers so as to solve the above problem.

According to an embodiment of the present invention, a frequency synthesizer is disclosed. The frequency synthesizer includes a PLL provided with an oscillator, a switching unit for switching the PLL to either an open loop status or a closed loop status, and a setting device for adjusting an oscillator frequency of the oscillator according to a reference clock and an oscillator signal generated from the oscillator when the PLL is in the open loop status, wherein a control signal of the oscillator is substantially constant when the PLL is in the open loop status.

According to another embodiment of the present invention, a frequency synthesizer is further disclosed. The frequency synthesizer includes: a PLL including an oscillator for generating an oscillator signal and a first frequency divider, for dividing a frequency of the oscillator signal to generate a first frequency-divided signal; a switching unit, for switching the PLL to either an open loop status or a closed loop status, wherein a control signal of the oscillator is substantially constant when the PLL is in the open loop status; a second frequency divider, for dividing a frequency of a reference clock to generate a second frequency-divided signal; a counter, for counting according to the first frequency-divided signal and the second frequency-divided signal to generate a counter value when the PLL is in the open loop status; a comparator, for comparing the counter value with a predetermined value to generate a comparing result; and a determining unit, for adjusting an oscillator frequency of the oscillator according to the comparing result.

According to an embodiment of the present invention, a method for adjusting an oscillator in a PLL is yet further disclosed. The method includes: switching the PLL to an open loop status, and maintaining a control signal of the oscillator at a constant level; adjusting an oscillator frequency of the oscillator according to a reference clock and an oscillator signal generated from the oscillator when the PLL is in the open loop status; switching the PLL to a closed loop status after the oscillator frequency of the oscillator attains a predetermined target; and adjusting the control signal of the oscillator according to the reference clock and the oscillator signal when the PLL is in the closed loop status.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a simplified block diagram of a frequency synthesizer according to a first embodiment of the present invention.

FIG. 2 is a flow chart showing an exemplary method for adjusting the oscillator of a PLL according to an embodiment of the present invention.

FIG. 3 shows a simplified block diagram of the practical implementation of a switching device according to another embodiment of the present invention.

FIG. 4 shows a simplified block diagram of a first embodiment of the comparing device of the present invention.

FIG. 5 shows a simplified block diagram of a second embodiment of the comparing device of the present invention.

FIG. 6 shows a diagram of the varactor tuning characteristics of a switched capacitor oscillator according to an embodiment of the present invention.

FIG. 7 shows a simplified block diagram of a frequency synthesizer according to a second embodiment of the present invention.

### DETAILED DESCRIPTION

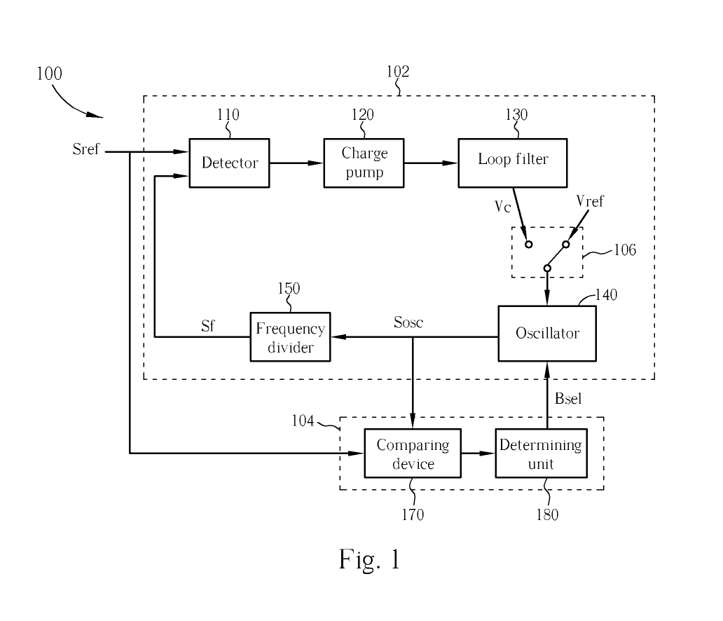

Please refer to FIG. 1. FIG. 1 shows a simplified block diagram of a frequency synthesizer 100 according to a first embodiment of the present invention. As shown in FIG. 1, the frequency synthesizer 100 includes a phase-locked loop (PLL) 102, a setting unit 104, and a switching device 106. The PLL 102 of the first embodiment includes: a detector 110 for detecting a frequency difference and/or a phase difference between a reference clock Sref and a frequency-divided signal Sf; a charge pump 120 for generating a control current according to a detecting result of the detector 110; a loop filter 130 for generating a control signal Vc according to the control current; an oscillator 140 for generating an oscillator signal Sosc according to the control signal Vc; and a frequency divider 150 for dividing frequency of the oscillator signal Sosc to generate the frequency-divided signal Sf. In practice, the detector 110 can be realized by utilizing a phase frequency detector (PFD), the loop filter 130 can be various kinds of active filters or passive filters, and the oscillator 140 can be realized by utilizing a switched capacitor voltage controlled oscillator (switched capacitor VCO).

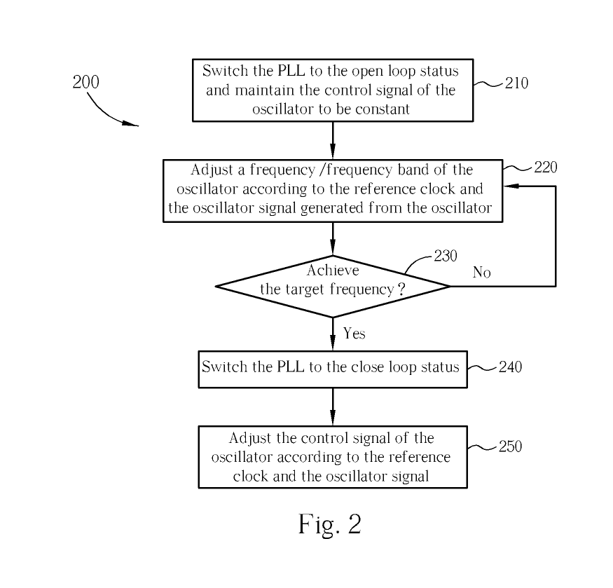

In the frequency synthesizer 100, the setting device 104 is utilized for adjusting an oscillator frequency of the oscillator 140, and the switching device 106 is utilized for switching the PLL 102 to either an open loop status or a closed loop status. The adjusting process of the oscillator 140 in the frequency synthesizer 100 can be divided into two modes, and the two modes are respectively a coarse tuning mode and a fine tuning mode. The switching device 106 will switch the PLL 102 to the open loop status in the coarse tuning mode, and the switching device 106 will switch the PLL 102 to the closed loop status in the fine tuning mode. The adjustment scheme of the oscillator 140 will be further described in the following paragraphs with reference to FIG. 2.

FIG. 2 is a flowchart 200 showing an exemplary method for adjusting the oscillator 140 of the PLL 102 according to an embodiment of the present invention. The steps included in the flowchart 200 will be described in the following paragraphs.

In the step 210, the switching device 106 will switch the PLL 102 to the open loop status, and maintain a control signal of an input node of the oscillator 140 at a constant level, so as to enter the coarse tuning mode. As shown in FIG. 1, the switching device 106 is coupled between the loop filter 130 and the oscillator 140 of the PLL 102. When the switching device 106 has switched the control signal of the oscillator 140 to a reference voltage Vref that is substantially constant, the PLL 102 will be in the open loop status. Please note that the above description is only an embodiment, and not a limitation of the practical implementation of the switching device 106 in the present invention.

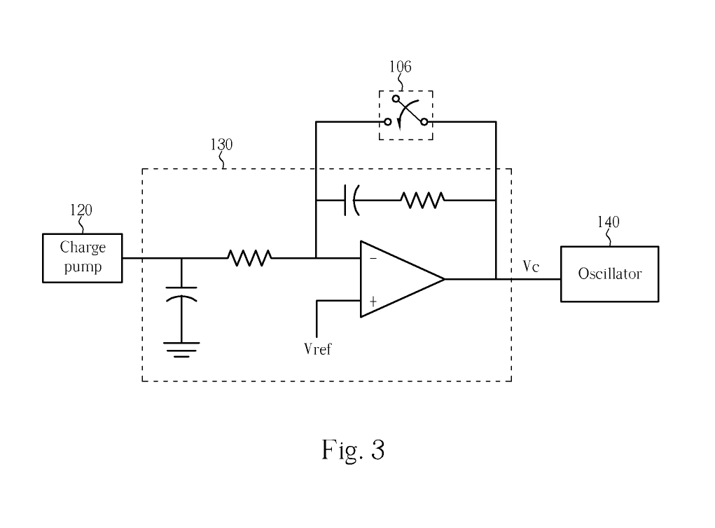

For example, FIG. 3 shows a simplified block diagram of the practical implementation of the switching device 106 according to another embodiment of the present invention. As shown in FIG. 3, the loop filter 130 is a filter having an operational amplifier-resistor-capacitor (OP-RC) architecture (i.e. OP-RC filter), and the switching device 106 is coupled between an input node and an output node of the operational amplifier of the loop filter 130. When the switching device 106 is turned on and the charge pump 120 is disabled, the control signal Vc outputted by the loop filter 130 will be equal to the reference voltage Vref that is substantially constant, and this condition is equivalent to that of the PLL 102 being in the open loop status.

When the PLL 102 is in the open loop status, the setting unit 104 will adjust a frequency and/or frequency band of the oscillator 140 according to the reference clock Sref and the oscillator signal Sosc generated from the oscillator 140 according to the reference voltage Vref when the PLL is in the open loop status (the step 220).

As shown in FIG. 1, the setting unit 104 of the first embodiment includes a comparing device 170 and a determining unit 180. The comparing device 170 is utilized for comparing the oscillator signal Sosc with the reference clock Sref, and the determining unit 180 is utilized for adjusting the frequency of the oscillator 140 according to a comparing result of the comparing device 170. For example, the comparing device 170 is able to compare the frequency of the oscillator signal Sosc with the frequency of the reference clock Sref so as to generate a comparing result, and the determining unit 180 is able to adjust the frequency of the oscillator 140 according to the comparing result in order to achieve the purpose of coarsely tuning the oscillator 140.

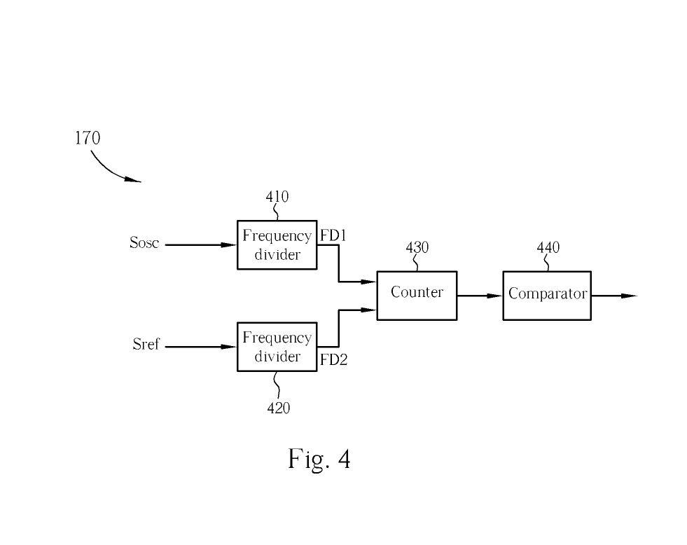

FIG. 4 shows a simplified block diagram of a first embodiment of the comparing device 170 of the present invention. The comparing device 170 of this first embodiment includes two frequency dividers 410 and 420, a counter 430, and a comparator 440. The frequency divider 410 is utilized for dividing frequency of the oscillator signal Sosc to generate a first frequency-divided signal FD1, and the frequency divider 420 is utilized for dividing frequency of the reference clock Sref to generate a second frequency-divided signal FD2. The counter 430 is utilized for counting according to the first frequency-divided signal FD1 and the second frequency-divided signal FD2 to generate a counter value, and the comparator 440 is utilized for comparing the counter value with a predetermined value to generate a comparing result.

Under a normal condition, a target frequency of the oscillator signal Sosc should be a frequency of the reference clock Sref multiplied by a divisor value of the frequency divider 150 in the PLL 102. For example, assuming that the frequency of the reference clock Sref is 100 MHz, and the divisor value of the frequency divider 150 is 4, then the target frequency of the oscillator signal Sosc should be 400 MHz. If the divisor value of the frequency divider 410 in the comparing device 170 is 5, and the divisor value of the frequency divider 420 is 10, then the frequency of the second frequency-divided signal FD2 is 10 MHz, and the frequency of the first frequency-divided signal FD1 should be 80 MHz. Thus, the counter 430 is able to count a number of rising edges (or falling edges) of the first frequency-divided signal FD1 during a period of the second frequency-divided signal FD2, and the comparator 440 is able to compare the counter value obtained by the counter 430 with a predetermined value 8 (=80/10) so as to determine whether the oscillator frequency of the oscillator 140 is the required value.

If the counter value is larger than the predetermined value 8, then it means that the oscillator frequency of the oscillator 140 is too high. If the counter value is smaller than the predetermined value 8, then it means that the oscillator frequency of the oscillator 140 is too low. If the counter value is equal to the predetermined value 8, then it means that the setting of the oscillator 140 at the time fits in with the required frequency range. In other words, the frequency band selected by the oscillator 140 at the time is a proper one. In practice, the divisor values of the frequency divider 410 and 420 are preferred to be integral values, and the predetermined value is preferred to be 2^{N} (wherein N is a positive integer) so as to reduce the complexity of the follow-up circuit.

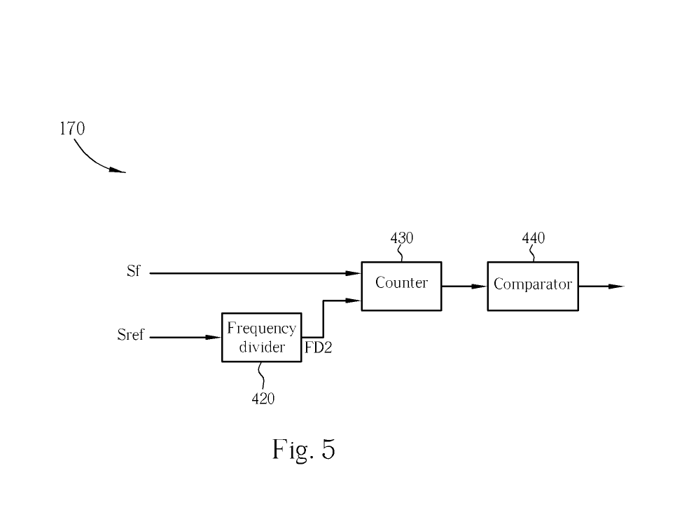

It can be seen from the above illustration that the comparing device 170 of the setting unit 104 is able to determine whether the setting of the oscillator 140 is appropriate by comparing the oscillator signal Sosc with the reference clock Sref, but this is only an embodiment, and not a limitation of the practical realization in the present invention. For example, FIG. 5 shows a simplified block diagram of a second embodiment of the comparing device 170 of the present invention. In this second embodiment, the counter 430 is utilized for counting according to the second frequency-divided signal FD2 and a frequency-divided signal Sf outputted by the frequency divider 150 of the PLL 102 to generate a counter value, and the comparator 440 is utilized for comparing the counter value of the counter 430 with a predetermined value to generate a comparing result. Similarly, the counter 430 is able to count a number of rising edges (or falling edges) of the frequency-divided signal Sf during a period of the second frequency-divided signal FD2, and the comparator 440 is only required to compare the counter value obtained by the counter 430 with a division value of the frequency divider 420 so as to determine whether the setting of the oscillator 140 is appropriate. In other words, the comparing device 170 of the setting unit 104 is also able to determine whether the setting of the oscillator 140 is appropriate by comparing the frequency-divided signal Sf with the reference clock Sref. In practice, the divisor values of the frequency divider 150 and 420 are preferred to be integral values, and the predetermined value is preferred to be 2^{N} (wherein N is a positive integer) so as to reduce the complexity of the follow-up circuit. In a preferred embodiment, the comparing device 170 and the PLL 102 is able to jointly use the same frequency divider 150 so as to reduce the square area of the whole circuit.

Next, the comparing device 170 will send the comparing result to the determining unit 180 so that the determining unit 180 is able to adjust the setting of the oscillator 140 according to the comparing result. For a specific description the oscillator 140 being realized by utilizing a switched capacitor oscillator is taken as an example. When the oscillator frequency of the switched capacitor oscillator is too high, the determining unit 180 will increase the total capacitance of the switched capacitor oscillator to lower the oscillator frequency of the switched capacitor oscillator, and when the oscillator frequency of the switched capacitor oscillator is too low, the determining unit 180 will decrease the total capacitance of the switched capacitor oscillator to increase the oscillator frequency of the switched capacitor oscillator. In practice, the determining unit 180 is able to use some algorithms such as a linear search algorithm, a binary search algorithm, or a successive approximation algorithm, during the process of adjusting a varactor setting value of the switched capacitor oscillator.

It can be seen from the above illustration that the setting unit 104 can be designed for adjusting the frequency of the oscillator 140 according to the reference clock Sref and the oscillator signal Sosc, or can be designed for adjusting the frequency of the oscillator 140 according to the reference clock Sref and the frequency-divided signal Sf.

In a preferred embodiment, when the oscillator 140 is realized by utilizing the switched capacitor oscillator, the setting unit 104 will further refer to the varactor tuning characteristics of the switched capacitor oscillator to select the frequency band of the switched capacitor oscillator in the step 220. For a further description, if the determining unit 180 of the setting unit 104 is not able to make the counter value of the counter 430 of the comparing device 170 equal to the predetermined value utilized by the comparator 440 by adjusting the varactor setting value of the of the switched capacitor oscillator, then the determining unit 180 of this preferred embodiment is able to determine a proper frequency band for the switched capacitor oscillator according to the varactor tuning characteristics of the switched capacitor oscillator.

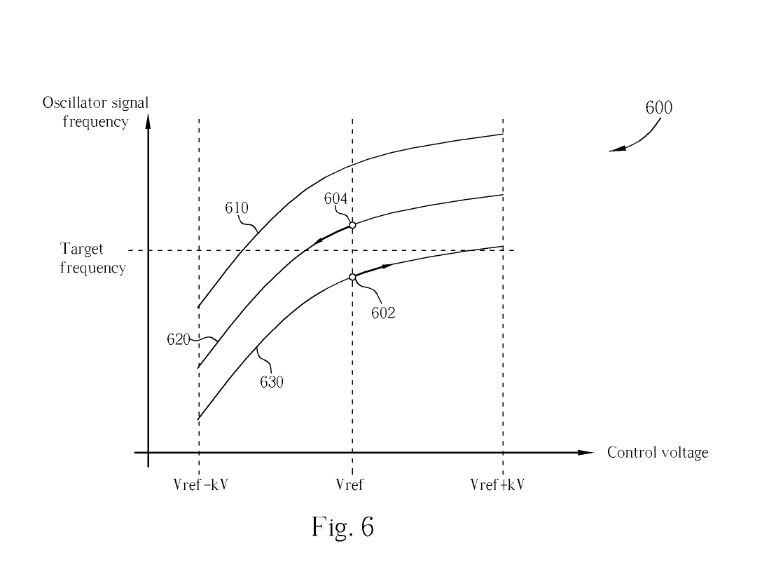

Please refer to FIG. 6. FIG. 6 shows a diagram of the varactor tuning characteristics of the switched capacitor oscillator according to an embodiment of the present invention. As shown in FIG. 6, 610, 620, and 630 represent three frequency bands that the switched capacitor oscillator is able to select, and the reference voltage Vref corresponds to the middle points of these frequency bands. Assuming that the frequency band currently selected by the switched capacitor oscillator is 630, then after the frequency synthesizer 100 enters the fine tuning mode, the switched capacitor oscillator has to be adjusted from the frequency point 602 at the current frequency band 630 along the upper right hand direction in order to achieve the position of the target frequency point. If the frequency band 620 is selected for the switched capacitor oscillator, then the switched capacitor oscillator has to be adjusted from the frequency point 604 at the frequency band 620 along the lower left hand direction in order to achieve the position of the target frequency point. As shown in FIG. 6, the varactor tuning characteristics curve in the right field of the frequency point 602 at the frequency band 630 has a more gradual slope, and the varactor tuning characteristics curve in the left field of the frequency point 604 at the frequency band 620 has a steeper slope. Thus, the determining unit 180 of the setting unit 104 will change the frequency band of the switched capacitor oscillator to the frequency band 620 so as to reduce the locking time after the frequency synthesizer 100 enters the fine tuning mode.

As shown in the flowchart 200 in FIG. 2, the setting unit 104 will perform the operation of the step 220 repeatedly before the oscillator 140 achieves the target frequency of the coarse tuning mode.

When the oscillator 140 achieves the target frequency of the coarse tuning mode (the step 230), the switching device 106 will switch the PLL 102 to the closed loop status (the step 240) in order to enter the fine tuning mode. In the first embodiment shown in FIG. 1, the switching device 106 will switch the input node of the oscillator 140 to the control signal Vc outputted by the loop filter 130, so as to make the PLL 102 be in the closed loop status. In the embodiment shown in FIG. 3, the switching device 106 will be turned off so as to make the PLL 102 be in the normal closed loop status.

When the PLL 102 is in the closed loop status, the PLL 102 will adjust the control signal Vc of the oscillator 140 according to the reference clock Sref and the oscillator signal Sosc (the step 250), so as to make the frequency of the oscillator signal Sosc achieve the required target frequency. Since the operational details related to the locking operation of the PLL 102 in the close loop status are well known to those of average skill in this art, further explanation is omitted herein for the sake of brevity.

The method for adjusting the oscillator mentioned above is also applicable to various schemes of the fractional-N frequency synthesizers.

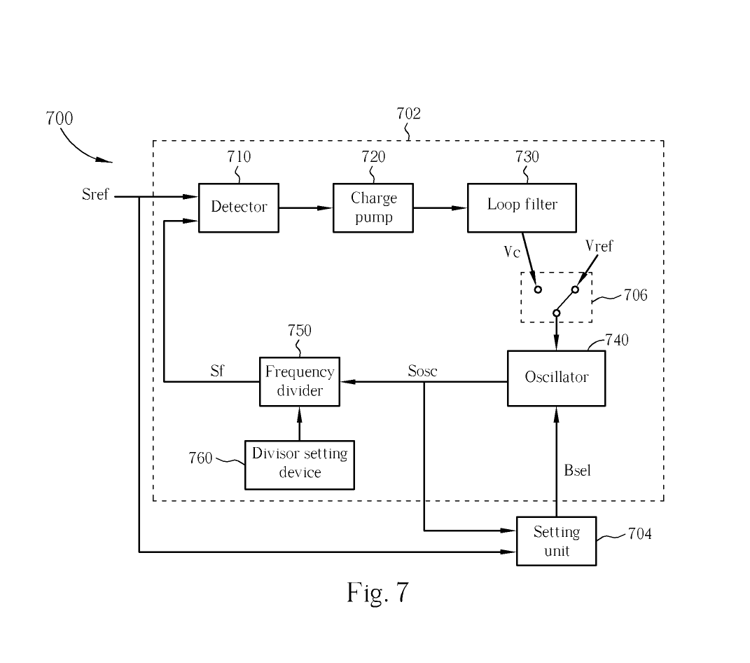

Please refer to FIG. 7. FIG. 7 shows a simplified block diagram of a frequency synthesizer 700 according to a second embodiment of the present invention. As shown in FIG. 7, the frequency synthesizer 700 includes a PLL 702, a setting unit 704, and a switching device 706. The PLL 702 of the second embodiment includes: a detector 710 utilizing for detecting a frequency difference and/or a phase difference between a reference clock Sref and a frequency-divided signal Sf; a charge pump 120 for generating a control current according to a detecting result of the detector 710; a loop filter 730 for generating a control signal Vc according to the control current; an oscillator 740 for generating an oscillator signal Sosc according to the control signal Vc; a frequency divider 750 for dividing frequency of the oscillator signal Sosc to generate the frequency-divided signal Sf; and a divisor setting device 760 for intermittently adjusting a divisor value of the frequency divider 750 so as to enable the frequency divider 750 perform a fractional-N frequency dividing operation.

As in the first embodiment mentioned above, the operation and implementation schemes of the setting unit 704 are also substantially the same as the setting unit 104. In other words, the setting unit 704 can be designed for adjusting the frequency of the oscillator 740 according to the reference clock Sref and the oscillator signal Sosc, or be designed for adjusting the frequency of the oscillator 740 according to the reference clock Sref and the frequency-divided signal Sf. However, please note that if the setting unit 704 adjusts the frequency/frequency band of the oscillator 740 according to the reference clock Sref and the frequency-divided signal Sf in the coarse tuning mode (i.e. if the PLL 702 is in the open loop status), then when the PLL 702 is in the open loop status, the divisor setting device 760 should set the divisor value of the frequency divider 750 to be a constant integral value. Since the operation and implementation schemes of the other elements of the PLL 702 are substantially the same as the first embodiment mentioned above, further explanation is omitted herein for the sake of brevity.

Similarly, the switching device 706 can be coupled between the loop filter 730 and the oscillator 740. If the loop filter 730 is a filter having an operational amplifier-resistor-capacitor (OP-RC) architecture (i.e. OP-RC filter), then the switching device 706 can also be coupled between an input node and an output node of the operational amplifier of the loop filter 730.

Since the frequency synthesizer mentioned above performs the coarse setting and adjustment for the oscillator (such as the switched capacitor oscillator) by the open loop scheme, and then performs the fine tuning for the control signal of the oscillator by the closed loop scheme, it is able to improve the calibrating speed of the oscillator effectively and further enhance the whole efficiency of the frequency synthesizer.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A frequency synthesizer, comprising:
a phase-locked loop (PLL), provided with an oscillator;
a switching unit, for switching the PLL to either an open loop status or a closed loop status; and
a setting device, for adjusting an oscillator frequency of the oscillator according to a reference clock and an oscillator signal generated from the oscillator when the PLL is in the open loop status;
wherein a control signal of the oscillator is substantially constant when the PLL is in the open loop status.

2. The frequency synthesizer of claim 1, wherein the PLL further comprises a loop filter, and the switching unit is coupled between the loop filter and the oscillator.

3. The frequency synthesizer of claim 1, wherein the PLL further comprises a loop filter having an operational amplifier-resistor-capacitor (OP-RC) architecture, and the switching unit is coupled between an input node and an output node of the operational amplifier.

4. The frequency synthesizer of claim 1, wherein the setting device sets a setting value of an internal element of the oscillator according to the reference clock and the oscillator signal for adjusting the oscillator frequency of the oscillator when the PLL is in the open loop status.

5. The frequency synthesizer of claim 1, wherein the oscillator is a switched capacitor oscillator.

6. The frequency synthesizer of claim 5, wherein the setting device sets a frequency band of the switched capacitor oscillator according to varactor tuning characteristics of the switched capacitor oscillator.

7. The frequency synthesizer of claim 1, wherein the PLL adjusts the control signal of the oscillator according to the reference clock and the oscillator signal when the PLL is in the closed loop status.

8. The frequency synthesizer of claim 7, wherein the PLL further comprises a first frequency divider for dividing a frequency of the oscillator signal to generate a first frequency-divided signal, and the PLL determines the control signal of the oscillator according to a frequency difference or a phase difference between the reference clock and the first frequency-divided signal when the PLL is in the closed loop status.

9. The frequency synthesizer of claim 8, wherein the setting device comprises:
a comparing device, for comparing the first frequency-divided signal with the reference clock; and
a determining unit, for adjusting the oscillator frequency of the oscillator according to a comparing result of the comparing device.

10. The frequency synthesizer of claim 9, wherein the comparing device comprises:
a second frequency divider, for dividing a frequency of the reference clock to generate a second frequency-divided signal;
a counter, for counting according to the first frequency-divided signal and the second frequency-divided signal to generate a counter value; and
a comparator, for comparing the counter value with a predetermined value to generate the comparing result.

11. The frequency synthesizer of claim 10, wherein the predetermined value is 2^{N}, and N is a positive integer.

12. The frequency synthesizer of claim 8, wherein a divisor of the first frequency divider is an integral value when the PLL is in the open loop status.

13. The frequency synthesizer of claim 1, wherein the setting device comprises:
a comparing device, for comparing the oscillator signal with the reference clock; and
a determining unit, for adjusting the oscillator frequency of the oscillator according to a comparing result of the comparing device.

14. The frequency synthesizer of claim 13, wherein the comparing device comprises:
a first frequency divider, for dividing a frequency of the oscillator signal to generate a first frequency-divided signal;
a second frequency divider, for dividing a frequency of the reference clock to generate a second frequency-divided signal;
a counter, for counting according to the first frequency-divided signal and the second frequency-divided signal to generate a counter value; and
a comparator, for comparing the counter value with a predetermined value to generate the comparing result.

15. The frequency synthesizer of claim 14, wherein a divisor of the first frequency divider is an integral value when the PLL is in the open loop status.

16. The frequency synthesizer of claim 14, wherein the predetermined value is 2^{N}, and N is a positive integer.

17. The frequency synthesizer of claim 13, wherein the switching unit switches the PLL to the closed loop status after the determining unit has adjusted the oscillator frequency of the oscillator.

18. A frequency synthesizer, comprising:
a PLL, comprising:
an oscillator, for generating an oscillator signal; and
a first frequency divider, for dividing a frequency of the oscillator signal to generate a first frequency-divided signal;
a switching unit, for switching the PLL to either an open loop status or a closed loop status, wherein a control signal of the oscillator is substantially constant when the PLL is in the open loop status;
a second frequency divider, for dividing a frequency of a reference clock to generate a second frequency-divided signal;
a counter, for counting according to the first frequency-divided signal and the second frequency-divided signal to generate a counter value when the PLL is in the open loop status;
a comparator, for comparing the counter value with a predetermined value to generate a comparing result; and
a determining unit, for adjusting an oscillator frequency of the oscillator according to the comparing result.

19. The frequency synthesizer of claim 18, wherein the predetermined value is 2^{N}, and N is a positive integer.

20. The frequency synthesizer of claim 18, wherein the PLL further comprises a loop filter, and the switching unit is coupled between the loop filter and the oscillator.

21. The frequency synthesizer of claim 18, wherein the PLL further comprises a loop filter having an operational amplifier-resistor-capacitor (OP-RC) architecture, and the switching unit is coupled between an input node and an output node of the operational amplifier.

22. The frequency synthesizer of claim 18, wherein the oscillator is a switched capacitor voltage-controlled oscillator (switched capacitor VCO).

23. The frequency synthesizer of claim 22, wherein the determining unit sets a frequency band of the switched capacitor VCO according to varactor tuning characteristics of the switched capacitor VCO.

24. The frequency synthesizer of claim 18, wherein the PLL determines the control signal of the oscillator according to a frequency difference or a phase difference between the reference clock and the first frequency-divided signal when the PLL is in the close loop status.

25. The frequency synthesizer of claim 18, wherein a divisor of the first frequency divider is an integral value when the PLL is in the open loop status.

26. The frequency synthesizer of claim 18, wherein the switching unit switches the PLL to the closed loop status after the determining unit has adjusted the oscillator frequency of the oscillator.

27. A method for adjusting an oscillator in a PLL, the method comprising:
switching the PLL to an open loop status, and maintaining a control signal of the oscillator to be constant;
adjusting an oscillator frequency of the oscillator according to a reference clock and an oscillator signal generated from the oscillator when the PLL is in the open loop status;
switching the PLL to a closed loop status after the oscillator frequency of the oscillator attains a predetermined target; and
adjusting the control signal of the oscillator according to the reference clock and the oscillator signal when the PLL is in the closed loop status.

28. The method of claim 27, wherein the step of adjusting the oscillator frequency of the oscillator further comprises:
dividing a frequency of the oscillator signal to generate a first frequency-divided signal;
comparing the first frequency-divided signal with the reference clock; and
adjusting the oscillator frequency of the oscillator according to a comparing result of comparing the first frequency-divided signal with the reference clock.

29. The method of claim 28, wherein the step of comparing the first frequency-divided signal with the reference clock further comprises:
dividing a frequency of the reference clock to generate a second frequency-divided signal;
counting according to the first frequency-divided signal and the second frequency-divided signal to generate a counter value; and
comparing the counter value with a predetermined value to generate the comparing result.

30. The method of claim 28, wherein a frequency dividing operation applied to the oscillator signal is an integral frequency dividing operation.

31. The method of claim 27, wherein the step of adjusting the oscillator frequency of the oscillator further comprises:
setting a frequency band of the oscillator according to varactor tuning characteristics of the oscillator.
